(19) United States
(12) Patent Application Publication
(10) Pub. No.: US 2016/0345453 A1
(43) Pub. Date: Nov. 24, 2016

(54) FIXING APPARATUS AND ELECTRONIC DEVICE HAVING SAME

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventors: GUANG-YI ZHANG, Shenzhen (CN); ZHAO-WEN ZOU, Shenzhen (CN)

(21) Appl. No.: 14/794,175

(22) Filed: Jul. 8, 2015

(30) Foreign Application Priority Data
May 18, 2015 (CN) 201510251995.3

(51) Int. Cl. H05K 5/03; H05K 5/00; H05K 5/02

(52) U.S. Cl. CPC H05K 5/03; H05K 5/0221; H05K 5/0004

(57) ABSTRACT

A fixing apparatus includes a supporting member defining a through hole and an opening, and a sliding member slidably mounted in the supporting member and including an engaging portion. An operating member is slidably mounted in the supporting member and is configured to slide the sliding member. A first pivoting member is pivotably mounted in the supporting member and is configured to be urged by the operating member. A second pivoting member is pivotably mounted in the supporting member and configured to be rotated by the first pivoting member, so extending a pushing plate out of the opening. In a locked position, the engaging portion extends out of the through hole and the pushing plate is located at a first position. In an unlocked position, the engaging portion is received in the supporting member and the pushing plate is located at a second position.

### FIELD

The subject matter herein generally relates to device supports.

### BACKGROUND

Generally, an electronic device comprises a main body and a cover capable of covering a front side of the main body. One end of the cover is pivotably coupled to one end of the front side of the main body, and the other end of the cover is detachably engaged with the other end of the front side of the main body.

### BRIEF DESCRIPTION OF THE DRAWINGS

Implementations of the present technology will now be described, by way of example only, with reference to the attached figures.

FIG. 1 is an assembled, isometric view of an embodiment of an electronic device comprising a main body, two symmetrical supporting members, two symmetrical fixing assemblies, and a cover.

FIG. 2 is an exploded, isometric view of a portion of the main body, one of the two symmetrical supporting members, and one of the two symmetrical fixing assemblies of FIG. 1, wherein the supporting member comprises a supporting plate and a housing.

FIG. 3 is an enlarged, isometric view of the housing of the other supporting member of FIG. 1.

FIG. 4 is an enlarged, isometric view of a fixing assembly of FIG. 2.

FIG. 5 is similar to FIG. 4, but viewed from another angle.

FIG. 6 is an assembled, isometric view of a fixing assembly and the housing of FIG. 2.

FIG. 7 is a cross sectional, isometric view of a portion of the electronic device of FIG. 1 taken along a line VII-VII, wherein the cover is locked.

FIG. 8 is a cross sectional, isometric view of a portion of the electronic device of FIG. 1 taken along the line VII-VII but viewed from an opposite direction, wherein the cover is locked.

FIG. 9 is similar to FIG. 7, wherein the cover is unlocked.

FIG. 10 is similar to FIG. 8, wherein the cover is unlocked.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other feature that the term modifies, such that the component need not be exact. For example, “substantially cylindrical” means that the object resembles a cylinder, but can have one or more deviations from a true cylinder. The term “inside” indicates that at least a portion of a region is partially contained within a boundary formed by the object. The term “comprising” means “including, but not necessarily limited to”; it specifically indicates open-ended inclusion or membership in a so-described combination, group, series and the like.

The present disclosure is described in relation to an electronic device.

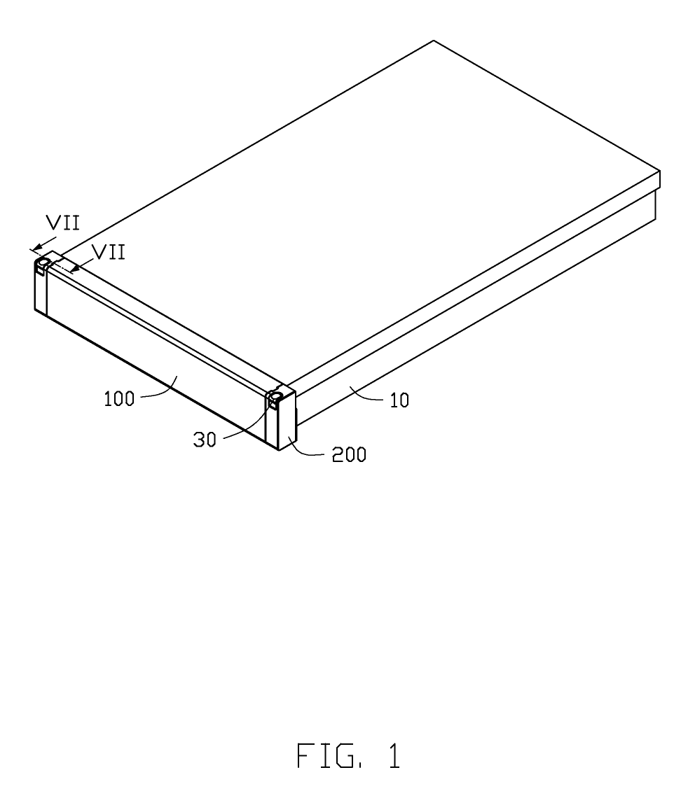

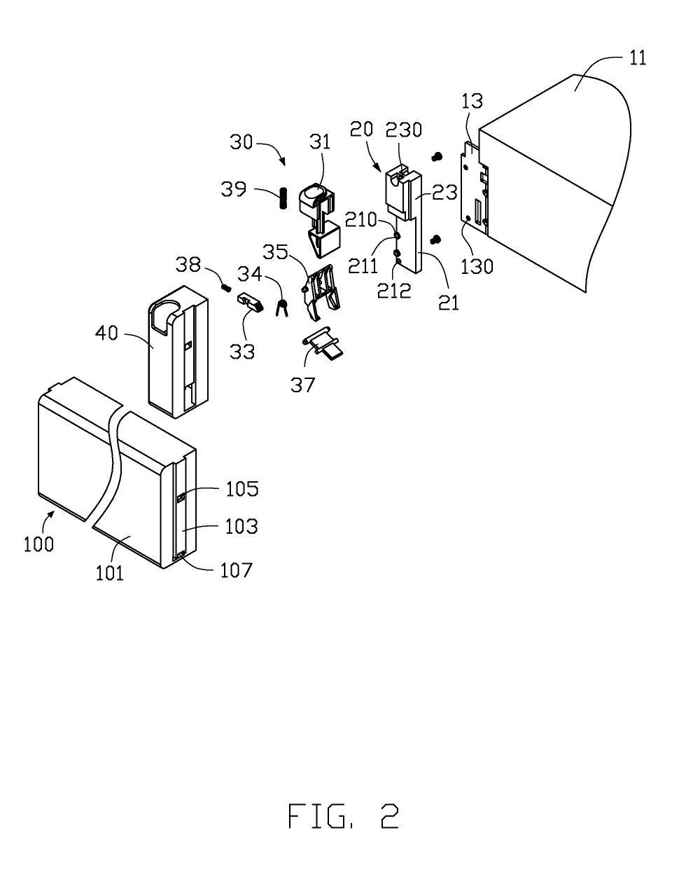

FIGS. 1 and 2 illustrate that an embodiment of the electronic device comprises a main body 10, two symmetrical supporting members 200, two symmetrical fixing assemblies 30, and a cover 100. In at least one embodiment, the main body 10 is a server.

The main body 10 comprises an enclosure 11 and two fixing plates 13 extending outward from front ends of opposite sides of the enclosure 11. Each fixing plate 13 defines two through holes 130.

The cover 100 comprises a base body 101 and two bars 103 extending outward from opposite end surfaces of the base body 101. An engaging groove 105 is defined in a middle portion of each bar 103. A securing hole 107 is defined in each end surface of the base body 101, between a bottom end of a bar 103 and a bottom surface of the base body 101.

One of the two supporting members 200 comprises a supporting plate 20 and a housing 40.

The supporting plate 20 comprises a base plate 21 and an extending block 23 extending up and frontward from a top surface of the base plate 21. Two spaced protrusions 210 extend frontward from a front surface of the base plate 21, near a first side of the base plate 21. A through hole 212 is defined in the base plate 21, near the two protrusions 210. Each protrusion 210 defines an axle hole 211. A through hole 230 is defined in a top surface of the extending block 23, extending through a front surface and a rear surface of the extending block 23.

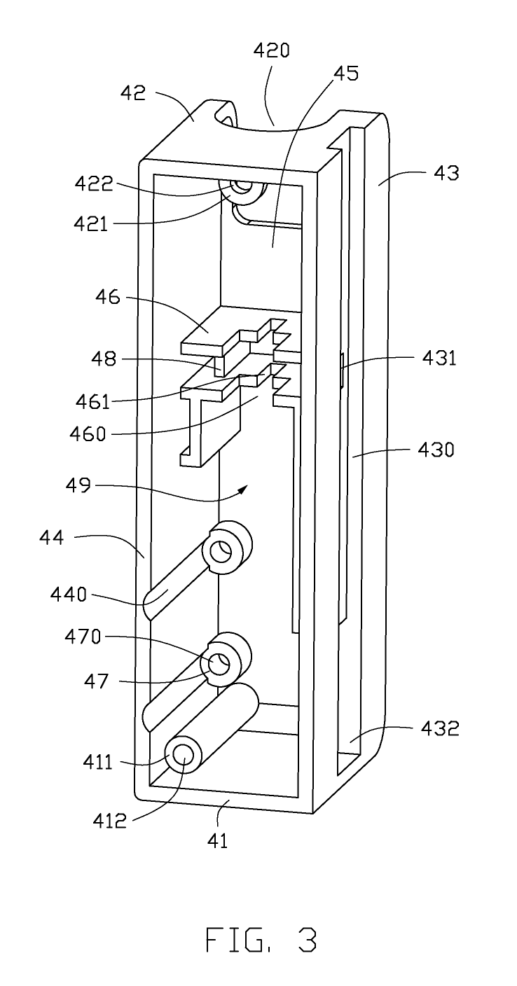

FIG. 3 illustrates that the housing 40 comprises a bottom board 41, a top board 42 parallel to and opposite to the bottom board 41, a first side board 43 perpendicularly extending up from a first side of the bottom board 41, a second side board 44 perpendicularly extending up from a second side opposite to the first side of the bottom board 41, a front end board 45 perpendicularly extending up from a front end of the bottom board 41, and two blocking boards 46 perpendicularly coupled between the first side board 43 and the second side board 44. The two blocking boards 46 are near the top board 42. The bottom board 41, the top board 42, the first side board 43, the second side board 44, and the front end board 45 are coupled together to form a housing interior 49. A fixing post 411 extends rearward from an inner surface of the front end board 45, near the second side board 44 and the bottom board 41. A fixing hole 412 is axially defined in the fixing post 411. An opening 420 is defined at a junction of the top board 42 and the front end board 45. A fixing board 421 extends down from a rear inside wall bounding the opening 420 of the top board 42. A fixing hole 422 is defined in a middle portion of the fixing board 421. A sliding slot 430 is defined in an outer surface of the first side board 43 extending through the top board 42. A through hole 431 communicating with the sliding slot 430 and the housing interior 49 is defined in an inside wall bounding the sliding slot 430 of the first side board 43, between the two blocking boards 46. An opening 432 communicating with the sliding slot 430 and the housing interior 49 is defined near the bottom board 41. Two spaced protruding platforms 47 extend rearward from the inner surface of the front end board 45, near the second side board 44 and between the two blocking boards 46 and the fixing post 411. Each protruding platform 47 defines a pivoting hole 470. An arced receiving groove 440 aligned with each protruding platform 47 is defined in an inner surface of the second side board 44. An opening 460 is defined in a rear end of each blocking board 46. A guiding groove 461 communicating with the opening 460 is defined in the blocking board 46. Two blocking plates 48 are perpendicularly coupled between the two blocking boards 46, at opposite sides of the two guiding grooves 461.

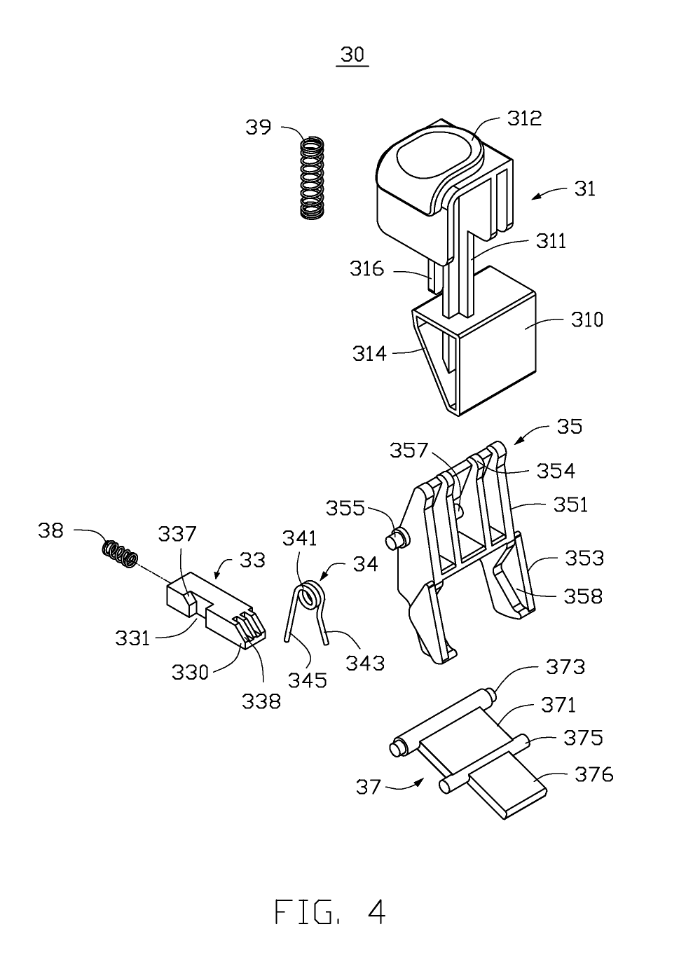

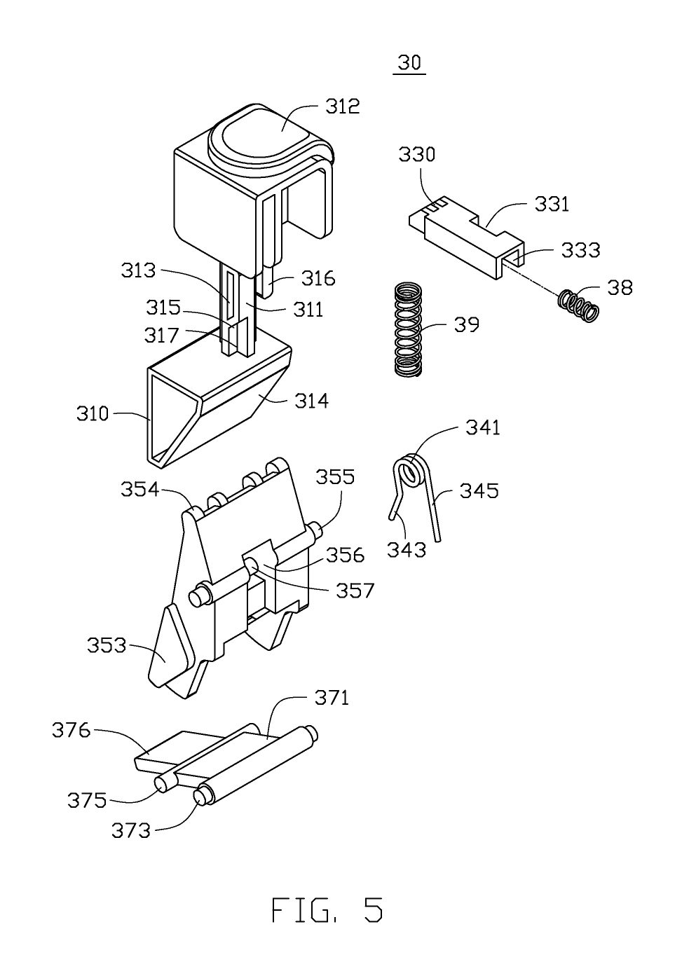

FIGS. 4 and 5 illustrate that one of the two fixing assemblies 30 comprises an operating member 31, a sliding member 33, a first pivoting member 35, a second pivoting member 37, a first elastic member 38, a second elastic member 39, and a third elastic member 34.

The operating member 31 comprises an urging block 310, a coupling portion 311 extending up from a top surface of the urging block 310, and an operating portion 312 extending up from a top end of the coupling portion 311. A slanted urging plate 314 extends down from a first side of the urging block 310, toward a second side opposite to the first side of the urging block 310. An urging portion 313 extends outward from a rear surface of the coupling portion 311. A notch 317 is defined in a bottom of the urging portion 313, near the urging plate 314. The urging portion 313 has a top inside bevel 315 bounding the notch 317. A guiding post 316 extends down from the operating portion 312, against the notch 317.

An engaging portion 330 extends outward from a first end of the sliding member 33. A guiding groove 331 is defined in a front surface of the sliding member 33, through a top surface and a bottom surface of the sliding member 33. A top inside bevel 337 bounding the guiding groove 331 extends from the top surface of the sliding member 33, near a second end opposite to the first end of the sliding member 33. A receiving groove 333 is defined in the second end of the sliding member 33. The engaging portion 330 has a slanted guiding surface 338 extending down from the top surface of the sliding member 33 and extending away from the second end of the sliding member 33.

The first pivoting member 35 comprises a pivoting frame 351 and two urging plates 353 extending down from a front end and a rear end of the pivoting frame 351. The two urging plates 353 extend away from a first side of the pivoting frame 351. A plurality of urging tabs 354 extends up from a top surface of the pivoting frame 351 and extends away from the first side of the pivoting frame 351, each urging tab 354 having a top arc surface. A shaft 355 is formed at a first side of the pivoting frame 351. A portion of the shaft 355 extends out of a first side surface of the pivoting frame 351, and a front end and a rear end of the shaft 355 extend through and out of a front surface and a rear surface of the pivoting frame 351. A notch 356 is defined in the first side surface of the pivoting frame 351, extending through the shaft 355. A protruding post 357 parallel to the shaft 355 extends from an inside wall bounding the notch 356 of the pivoting frame 351. A substantially triangular urging groove 358 is defined in an inner surface of each urging plate 353, away from the shaft 355.

The second pivoting member 37 comprises a coupling plate 371, a spindle 373 formed at a first end of the coupling plate 371, an urging post 375 formed at a second end opposite to the first end of the coupling plate 371 and parallel to the spindle 373, and a pushing plate 376 extending from a side of the urging post 375 against the coupling plate 371. A front end and a rear end of the spindle 373 extend out of a front surface and a rear surface of the coupling plate 371, and a front end and a rear end of the urging post 375 extend out of the front surface and the rear surface of the coupling plate 371.

In at least one embodiment, the first elastic member 38 and the second elastic member 39 are coil springs. The third elastic member 34 is a torsion spring. The third elastic member 34 comprises a base body 341, a first pin 343, and a second pin 345 extending outward from two ends of the base body 341.

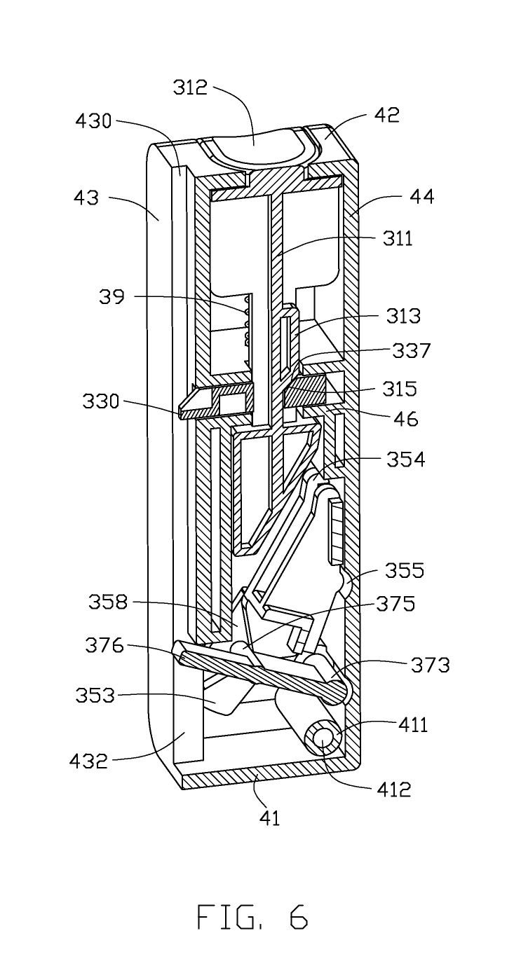

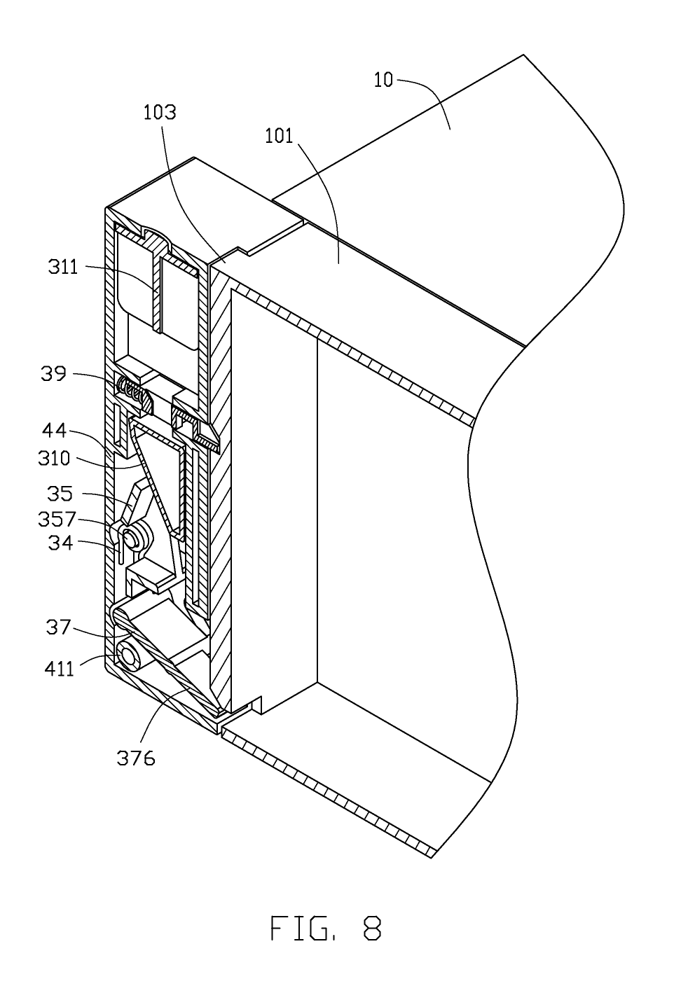

FIGS. 2-6 and 8 illustrate one of the two symmetrical supporting members 200 and one of the two fixing assemblies 30 in an assembly process. The first elastic member 38 is received in the receiving groove 333 of the sliding member 33. The sliding member 33 is placed between the two blocking boards 46, to align the engaging portion 330 with the through hole 431. The first elastic member 38 is arranged between the second side board 44 and an inside wall bounding the receiving groove 333 of the sliding member 33. In an original state, the first elastic member 38 urges against the sliding member 33 to extend the engaging portion 330 through the through hole 431 to be received in the sliding slot 430.

The second elastic member 39 is placed around the guiding post 316. The operating member 31 is received in the housing interior 49. A top of the operating portion 312 is received in the opening 420 and contacts the top board 42. The coupling portion 311 can slide up and down along the two openings 460. The urging portion 313 can slide up and down along the guiding groove 331. The bevel 315 is aligned with the bevel 337. The guiding post 316 can slide up and down along the guiding grooves 461. The second elastic member 39 is arranged between the blocking board 46 near the top board 42 and the operating portion 312.

The second pivoting member 37 is placed between the two urging plates 353, to slidably locate the front end and the rear end of the urging post 375 in the two urging grooves 358. The spindle 373 and the shaft 355 are located at the same side of the urging post 375. Thus, the first pivoting member 35 is pivotably coupled to the second pivoting member 37. The base body 341 of the third elastic member 34 is arranged around the protruding post 357. The first pin 343 of the third elastic member 34 urges against a bottom of the pivoting frame 351. Thus, the third elastic member 34 is attached to the first pivoting member 35. The front end of the shaft 355 is pivotably received in the pivoting hole 470 near the top board 42, and the portion of the shaft 355 is received in the receiving groove 440 near the top board 42. The front end of the spindle 373 is pivotably received in the pivoting hole 470 away from the top board 42, and a portion of the spindle 373 is received in the receiving groove 440 near the bottom board 42. The pushing plate 376 extends out of the opening 432. The second pin 345 of the third elastic member 34 urges against the second side board 44. Thus, the first pivoting member 35 and the second pivoting member 37 are pivotably mounted in the housing interior 49, and the third elastic member 34 is mounted in the housing interior 49. In the original state, the pushing plate 376 extends up and away from the bottom board 41.

The through hole 212 is aligned with the fixing hole 412 and the through hole 230 is aligned with the fixing hole 422. The rear end of the shaft 355 and the rear end of the spindle 373 are pivotably received in the two axle holes 211, to couple the first pivoting member 35 and the second pivoting member 37 between the housing 40 and the supporting plate 20. A fixing member extends through the through hole 230 and is fixed in the fixing hole 422, and a fixing member extends through the through hole 212 and is fixed in the fixing hole 412. Thus, the supporting plate 20 covers the housing 40.

The other supporting member 200 and the other fixing assembly 30 are assembled in a similar way.

The two supporting members 200 are arranged in front of the main body 10, to contact the two supporting plates 20 with front side faces of the two fixing plates 13 and align the two sliding slots 430. A plurality of fixing members (not shown) extends through the through holes 130 and is fixed in the two supporting plates 20. Thus, the two supporting members 200 are attached to the two fixing plates 13.

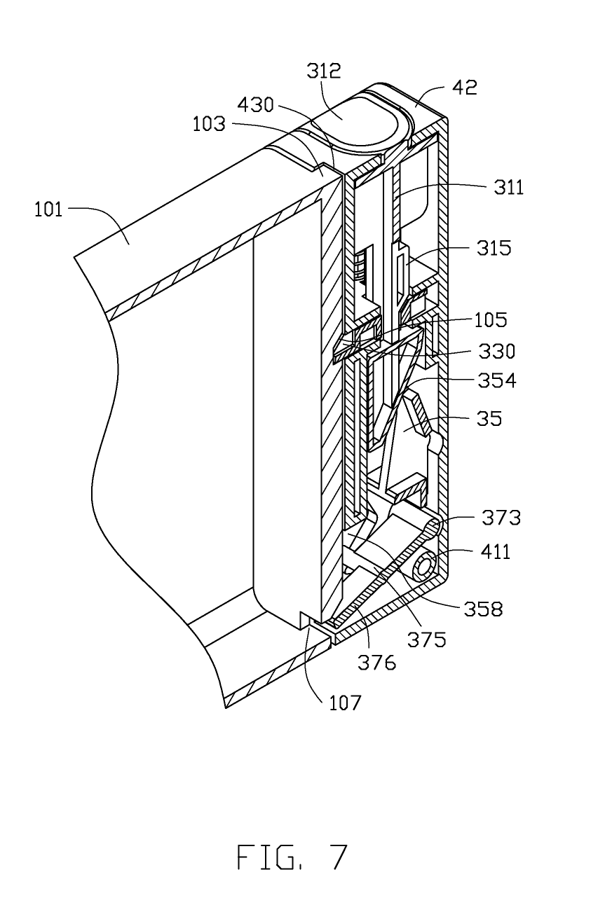

FIGS. 1-2 and 7-8 illustrate the cover 100 and the main body 10 in an assembly process. The cover 100 is placed between the two supporting members 200, to align the two bars 103 with the two sliding slots 430. The bottom ends of the two bars 103 push against the two guiding surfaces 338, to move the two blocking members 33 in a first direction substantially parallel to the bottom board 41. This elastically deforms the two first elastic members 38 until the two engaging portions 330 are received in the two through holes 431. The two blocking members 33 slide the two operating members 31 in a second direction, which is substantially perpendicular to the first direction. The two bars 103 further slide along the two sliding slots 430. The bottom ends of the two bars 103 push against the two pushing plates 376. The two spindles 373 pivot in a third direction to urge the two urging posts 375 down against inside walls bounding the urging grooves 358. The two shafts 355 are rotated in a fourth direction to move the plurality of urging tabs 354 of the two first pivoting members 35 away from the two second side boards 44 and elastically deform the two third elastic members 34. This moves the two operating members 31 in the second direction. When the two engaging grooves 105 are aligned with the two engaging portions 330, the two third elastic members 34 elastically recover to restore the two blocking members 33. The two blocking members 33 then engage the two engaging portions 330 in the two engaging grooves 105 so as to latch the cover 100 between the two supporting members 200. The two pushing plates 376 are located at a first position, urging against the bottom ends of the two bars 103 and near the two securing holes 107.

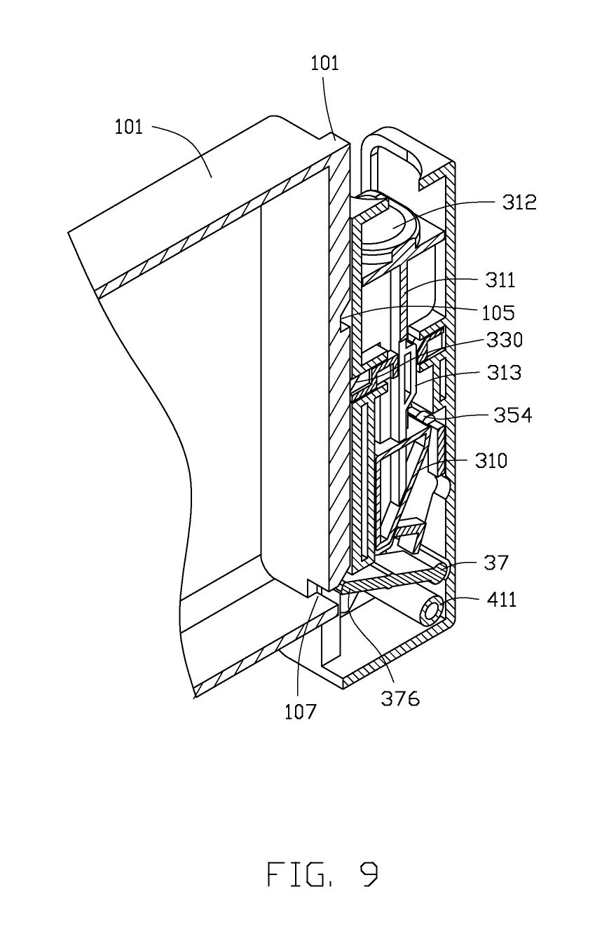

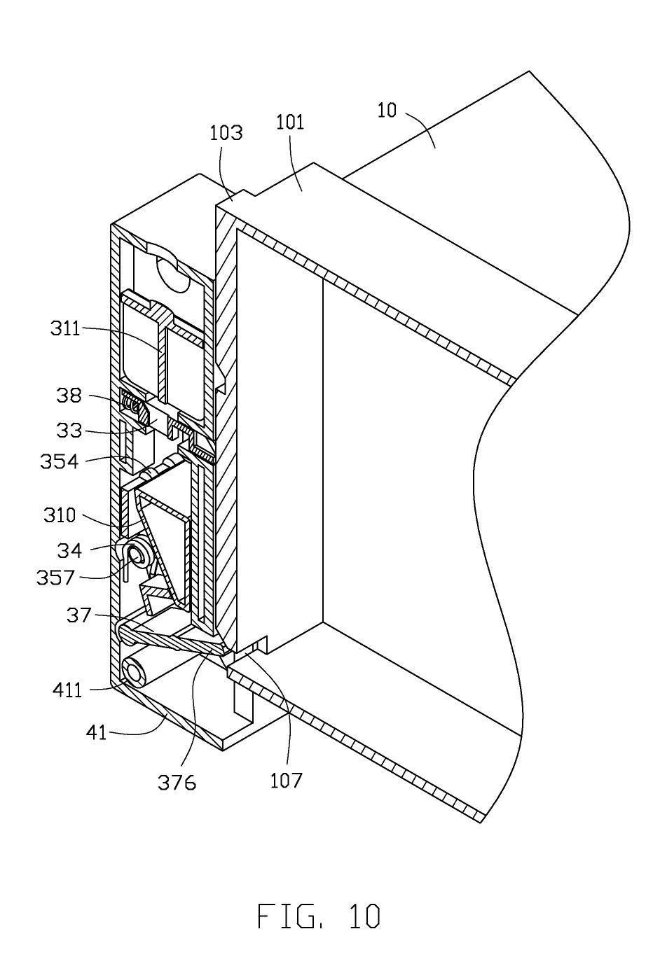

FIGS. 9 and 10 illustrate disassembly of the cover 100 and the main body 10. The two operating portions 312 are pressed to slide the two operating members 31 in a direction opposite to the first direction and elastically deform the two second elastic members 39. The two bevels 315 urge against the two bevels 337 to move the two blocking members 33 in the second direction, disengaging the two engaging portions 330 from the two engaging grooves 105. The two blocking members 33 elastically deform the two first elastic members 38. The two operating portions 312 are further pressed to urge the two urging plates 314 against the plurality of urging tabs 354 of the two first pivoting members 35. The plurality of urging tabs 354 of the two first pivoting members 35 move toward the second side boards 44 to rotate the two shafts 355 in a direction opposite to the fourth direction. The two third elastic members 34 elastically recover to further rotate the two first pivoting members 35 in a direction opposite to the fourth direction. The inside walls bounding the urging grooves 358 of the two first pivoting members 35 urge against the two urging posts 375 to rotate the two spindles 373 in a direction opposite to the third direction. The two pushing plates 376 are located at a second position, urging against top inside walls bounding the two securing holes 107 of the cover 100, to expose a top of the cover 100 out of top surfaces of the two top boards 42, to allow for easy removal of the cover 100. The two operating portions 312 are released. The two second elastic members 39 elastically recover to restore the two operating portions 312. The two first elastic members 38 elastically recover to restore the two blocking members 33.

The embodiments shown and described above are only examples. Many details are often found in the art such as the other features of an electronic device.

Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A fixing apparatus comprising:
a supporting member defining a through hole and an opening;
a sliding member slidably mounted in the supporting member and comprising an engaging portion;
an operating member slidable relative to the supporting member to slide the sliding member from a locked position to an unlocked position;
a first pivoting member pivotably mounted in the supporting member and configured to be urged by the operating member; and
a second pivoting member pivotably mounted in the supporting member and configured to be rotated by the first pivoting member, the second pivoting member comprising a pushing plate extending out of the opening;
wherein in the locked position, the engaging portion extends out of the through hole and the pushing plate is located at a first position; and in the unlocked position, the engaging portion is received in the supporting member and the pushing plate is located at a second position.

2. The fixing apparatus of claim 1, wherein the operating member comprises a coupling portion and an urging portion located on the coupling portion, the sliding member defines a guiding groove, and the urging portion is configured to extend through the guiding groove to slide the sliding member.

3. The fixing apparatus of claim 2, wherein the sliding member comprises a bevel bounding the guiding groove, the urging portion has a bevel configured to urge against the bevel of the sliding member.

4. The fixing apparatus of claim 2, wherein the operating member further comprises an urging block coupled to the coupling portion, the first pivoting member comprises a pivoting frame pivotably mounted in the supporting member, and the urging block is configured to urge against the pivoting frame.

5. The fixing apparatus of claim 4, wherein the first pivoting member further comprises two urging plates located on the pivoting frame, the second pivoting member comprises an urging post arranged between the two urging plates.

6. The fixing apparatus of claim 5, wherein the second pivoting member further comprises a coupling plate and a spindle located at a first side of the coupling plate, the urging post is located at a second of the coupling plate, the spindle is pivotably mounted in the supporting member.

7. The fixing apparatus of claim 1, further comprising a first elastic member arranged between the sliding member and the supporting member.

8. The fixing apparatus of claim 1, further comprising a second elastic member arranged between the operating member and the supporting member.

9. The fixing apparatus of claim 1, further comprising a third elastic member arranged between the first pivoting member and the supporting member.

10. The fixing apparatus of claim 1, wherein the sliding member is slidable in a first direction, the operating member is slidable in a second direction perpendicular to the first direction.

11. An electronic device comprising:
a main body;
two symmetrical supporting members coupled to opposite ends of a front side of the main body, each supporting member defining a through hole;
a cover arranged between the two supporting members, two engaging grooves and two securing holes defined in opposite ends of the cover; and
two sliding member slidably mounted in the two supporting members, each sliding member comprising an engaging portion;
two operating members slidable relative to the two supporting members to slide the two sliding members from a locked position to an unlocked position;
two first pivoting members pivotably mounted in the two supporting member and configured to be urged by the two operating members; and
two second pivoting members pivotably mounted in the two supporting members and configured to be rotated by the two first pivoting members, the two second pivoting members comprising two pushing plates extending out of the two openings and extending into the two securing holes;
wherein in the locked position, the two engaging portions extend out of the two through holes to be engaged in the two engaging grooves and the two pushing plates are located at a first position; and in the unlocked position, the two engaging portions are disengaged from the two engaging grooves and the two pushing plates are located at a second position to lift up the cover.

12. The electronic device of claim 11, wherein each operating member comprises a coupling portion and an urging portion located on the coupling portion, each sliding member defines a guiding groove, and the urging portion is configured to extend through a corresponding guiding groove to slide a corresponding sliding member.

13. The electronic device of claim 12, wherein each sliding member comprises a bevel bounding the guiding groove, each urging portion has a bevel configured to urge against the bevel of a corresponding sliding member.

14. The electronic device of claim 12, wherein each operating member further comprises an urging block coupled to the coupling portion, each first pivoting member comprises a pivoting frame pivotably mounted in the supporting member, and the urging block is configured to urge against a corresponding pivoting frame.

15. The electronic device of claim 14, wherein each first pivoting member further comprises two urging plates located on the pivoting frame, each second pivoting member comprises an urging post arranged between the two corresponding urging plates.

16. The electronic device of claim 15, wherein each second pivoting member further comprises a coupling plate and a spindle located at a first side of the coupling plate, the urging post is located at a second of a corresponding coupling plate, the spindle is pivotably mounted in a corresponding supporting member.

17. The electronic device of claim 11, further comprising two first elastic members arranged between the two sliding members and the two supporting members.

18. The electronic device of claim 11, further comprising two second elastic members arranged between the two operating members and the two supporting members.

19. The electronic device of claim 11, further comprising two third elastic members arranged between the two first pivoting members and the two supporting members.

20. The electronic device of claim 11, wherein the two sliding members are slidable in a first direction, the two operating members are slidable in a second direction perpendicular to the first direction.
